(19) United States
(12) Patent Application Publication
(10) Pub. No.: US 2025/0246488 A1
(43) Pub. Date: Jul. 31, 2025

(54) SUBSTRATE CIRCUIT STRUCTURE

(71) Applicant: Innolux Corporation, Miaoli County (TW)

(72) Inventors: Shu-Ling Wu, Miaoli County (TW); Zhi-Fu Huang, Miaoli County (TW)

(73) Assignee: Innolux Corporation, Miaoli County (TW)

(21) Appl. No.: 19/002,750

(22) Filed: Dec. 27, 2024

Related U.S. Application Data
(60) Provisional application No. 63/625,285, filed on Jan. 26, 2024.

(30) Foreign Application Priority Data
Sep. 4, 2024 (CN) 202411235069.2

(51) Int. Cl. H01L 21/66

(52) U.S. Cl. CPC H01L 22/32

(57) ABSTRACT

A substrate circuit structure includes a substrate and a circuit layer. The substrate includes an active region and a peripheral region adjacent to the active region. The circuit layer is disposed on the substrate and includes an electrostatic test region disposed in at least one of the active region and the peripheral region. The electrostatic test region includes a first test pad and a second test pad. The first test pad corresponds to a first breakdown voltage. The second test pad is disposed adjacent to the first test pad and corresponds to a second breakdown voltage different from the first breakdown voltage.

### CROSS-REFERENCE TO RELATED APPLICATION

This application claims the priority benefit of U.S. provisional application Ser. No. 63/625,285, filed on Jan. 26, 2024, and China application serial no. 202411235069.2, filed on Sep. 4, 2024. The entirety of each of the above-mentioned patent applications is hereby incorporated by reference herein and made a part of this specification.

### BACKGROUND

### Technical Field

The disclosure relates to an electronic device, and in particular to a substrate circuit structure.

### Description of Related Art

In the early stages of product development, an electrostatic testing structure is needed to understand the allowable electrostatic value range of the product, and to monitor whether there are suspicious factors in the environment or manufacturing process that may cause element damage or even product failure.

### SUMMARY

The disclosure provides a substrate circuit structure that can be used to monitor electrostatic discharge (ESD) phenomena in the manufacturing process.

According to an embodiment of the disclosure, a substrate circuit structure includes a substrate and a circuit layer. The substrate includes an active region and a peripheral region adjacent to the active region. The circuit layer is disposed on the substrate and includes an electrostatic test region disposed in at least one of the active region and the peripheral region. The electrostatic test region includes a first test pad and a second test pad. The first test pad corresponds to a first breakdown voltage. The second test pad is disposed adjacent to the first test pad and corresponds to a second breakdown voltage different from the first breakdown voltage.

In order to make the above-mentioned features and advantages of the disclosure comprehensible, embodiments accompanied with drawings are described in detail below.

### BRIEF DESCRIPTION OF THE DRAWINGS

The accompanying drawings are included to provide a further understanding of the disclosure, and are incorporated in and constitute a portion of this specification. The drawings illustrate exemplary embodiments of the disclosure and, together with the description, serve to explain the principles of the disclosure.

FIG. 1 is a schematic top view of a substrate circuit structure according to some embodiments of the disclosure.

FIG. 2 is a first enlarged schematic diagram of an electrostatic test region in FIG. 1.

FIG. 3 is a schematic cross-sectional view along a sectional line I-I′ in FIG. 2.

FIG. 4 is a second enlarged schematic diagram of the electrostatic test region in FIG. 1.

FIG. 5 is a schematic cross-sectional view along a sectional line II-II′ in FIG. 4.

FIG. 6 is a third enlarged schematic diagram of the electrostatic test region in FIG. 1.

FIG. 7 and FIG. 8 are schematic cross-sectional views taken along a sectional line III-III′ and a sectional line IV-IV′ in FIG. 6, respectively.

FIG. 9 is a fourth enlarged schematic diagram of the electrostatic test region in FIG. 1.

FIG. 10 and FIG. 11 are schematic cross-sectional views taken along a sectional line V-V′ and a sectional line VI-VI′ in FIG. 9, respectively.

FIG. 12 is a schematic flowchart of an electrostatic discharge detection method according to some embodiments of the disclosure.

### DESCRIPTION OF THE EMBODIMENTS

Reference will now be made in detail to the exemplary embodiments of the disclosure, examples of which are illustrated in the accompanying drawings. Wherever possible, the same reference numerals are used in the drawings and description to refer to the same or like parts.

Some terms are used to refer to specific elements throughout the description and the appended claims of the disclosure. A person skilled in the art should understand that an electronic device manufacturer may use different names to refer to the same elements. The disclosure is not intended to distinguish elements that have the same functions but different names. In the description and the claims hereinafter, terms such as “include”, “comprise”, and “have’ are open-ended terms, and should thus be interpreted as “including, but not limited to”.

The directional terms mentioned herein, like “above”, “below”, “front”, “rear, “left”, “right”, and the like, refer only to the directions in the accompanying drawings. Therefore, the directional terms are used for describing instead of limiting the disclosure. Each of the drawings illustrate typical features of methods, structures, and/or materials used in specific embodiments. Nonetheless, the drawings should not be interpreted as defining or limiting ranges or properties encompassed by these embodiments. For example, the relative sizes, thicknesses, and positions of film layers, regions, and/or structures may be reduced or enlarged for clarity.

In the disclosure, when a structure (or layer, element, substrate) is described as being located on/above another structure (or layer, element, substrate), it may refer to the case that the two structures are adjacent and directly connected, or the two structures are adjacent but not directly connected. Non-direct connection refers to the case that at least one intermediary structure (or intermediary layer, intermediary element, intermediary substrate, intermediary spacing) is present between the two structures, where a lower side surface of one structure is adjacent to or directly connected to an upper side surface of the intermediary structure, and an upper side surface of the other structure is adjacent to or directly connected to a lower side surface of the intermediary structure. The intermediary structure may be composed of a single-layer or multi-layer physical structure or non-physical structure with no limitation. In the disclosure, when a structure is disposed “on” another structure, it is possible that the structure is “directly” on the another structure, or the structure is “indirectly” on the another structure, namely at least one structure is further sandwiched between the structure and the another structure.

The terms “about”, “equal”, “equivalent”, “same”, “substantially”, or “essentially” are generally interpreted as that a value is within 20% of a given value or range, or within 10%, 5%, 3%, 2%, 1%, or 0.5% of a given value or range. In addition, the description “the range is from a first value to a second value” or “the range falls within a range of a first value to a second value” indicates that the range includes the first value, the second value, and other values in between.

In the description and the claims, the use of an ordinal number such as “first”, “second”, and so on to modify an element does not by itself connote or represent any preceding ordinal number of the element(s); any priority, precedence, or order of one element over another; or the order in which a manufacturing method is performed, but only to clearly distinguish an element having a certain name from another element having the same name. The same terms may be not used in the claims as used in the description, and accordingly a first member in the description may be a second member in the claims.

The term electrically connection or coupling described in the disclosure refers to direct or indirect connection. In the case of direct connection, end points of elements on two circuits are directly connected or interconnected by a conductor line segment. In the case of indirect connection, present between end points of elements on two circuits is a switch, a diode, a capacitor, an inductor, other suitable elements, or a combination of the above elements, but not limited thereto.

In the disclosure, a thickness, a length, and a width may be measured using an optical microscope (OM), and the thickness or width may be measured from a cross-sectional image shown in an electron microscope, but not limited thereto. In addition, certain errors may exist between any two values or directions for comparison. If a first value is equal to a second value, it implies that there may be an error of about 10% between the first value and the second value. If a first direction is perpendicular to a second direction, the angle between the first direction and the second direction may be between 80 degrees and 100 degrees. If a first direction is parallel to a second direction, the angle between the first direction and the second direction may be between 0 degree and 10 degrees. Furthermore, the terms “equal”, “equivalent”, “same”, “substantially”, or “essentially” mentioned herein typically represents that a value is within 10% of a given value or range. Moreover, the description “a given range is from a first value to a second value” or “a given range falls within a range of a first value to a second value” indicates that the given range includes the first value, the second value, and other values in between. If a first direction is perpendicular to a second direction, the angle between the first direction and the second direction may be between 80 degrees and 100 degrees. If a first direction is parallel to a second direction, the angle between the first direction and the second direction may be between 0 degree and 10 degrees.

Unless otherwise defined, all terms (including technical and scientific terms) used herein have the same meaning as commonly understood by one of ordinary skill in the art related to the disclosure. It will be understood that terms, such as those defined in commonly used dictionaries, should be interpreted as having a meaning that is consistent with their meaning in the background or the context of the relevant art and the disclosure and will not be interpreted in an idealized or overly formal sense unless particularly so defined in the embodiments of the disclosure.

In the disclosure, an electronic device may include a display device, a backlight device, an antenna device, a packaging device, a sensing device or a tiled device, but not limited thereto. The electronic device may be a bendable or flexible electronic device. The display device may be a non-self-luminous display device or a self-luminous display device. The display device may include, for example, a liquid crystal (liquid crystal), a light-emitting diode (LED), fluorescence, phosphorescence, quantum dot (QD), other suitable display media, or a combination thereof. The antenna device may include, for example, a reconfigurable intelligent surface (RIS), a frequency selective surface (FSS), a radio frequency filter (RF-Filter), a polarizer, a resonator, an antenna or the like. The antenna may be a liquid crystal antenna or a varactor diode antenna. The sensing device may be a sensing device that senses capacitance, light, thermal energy or ultrasonic waves, but not limited thereto. In the disclosure, the electronic device may include electronic elements, and the electronic elements may include passive elements and active elements, such as capacitors, resistors, inductors, diodes, transistors, or the like. Diodes may include light-emitting diodes, varactor diodes or photodiodes. The light-emitting diode may include, for example, an organic light-emitting diode (OLED), a mini LED, a micro LED or a quantum dot LED, but not limited thereto. The tiled device may be, for example, a display tiled device or an antenna tiled device, but not limited thereto. It should be noted that the electronic device can be any combination of the above, but not limited thereto. The packaging device may be suitable for wafer-level packaging (WLP) technology or panel-level packaging (PLP) technology, such as a packaging device for chip first process or chip last process. In addition, the shape of the electronic device may be a rectangular shape, a circular shape, a polygonal shape, a shape with curved edges, or other suitable shapes. The electronic device may have peripheral systems such as a driving system, a control system, a light source system, or the like to support a display device, an antenna device, a wearable device (including augmented reality or virtual reality, for example), vehicle mounted device (including an automotive windshield, for example), or a tiled device.

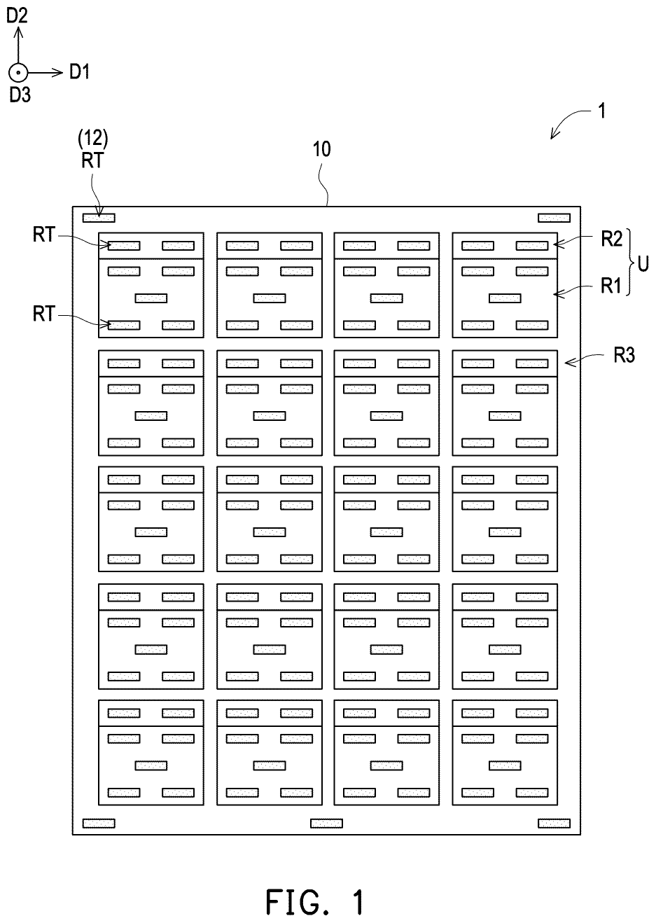

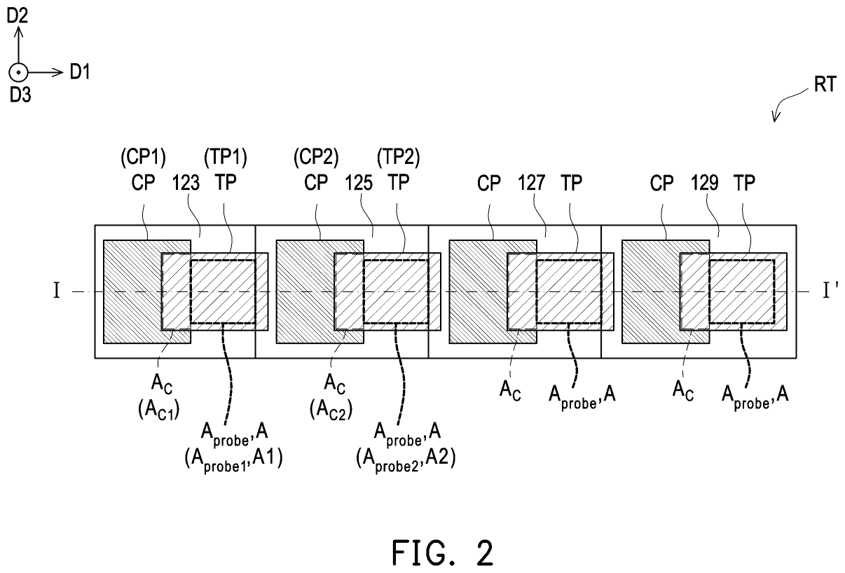

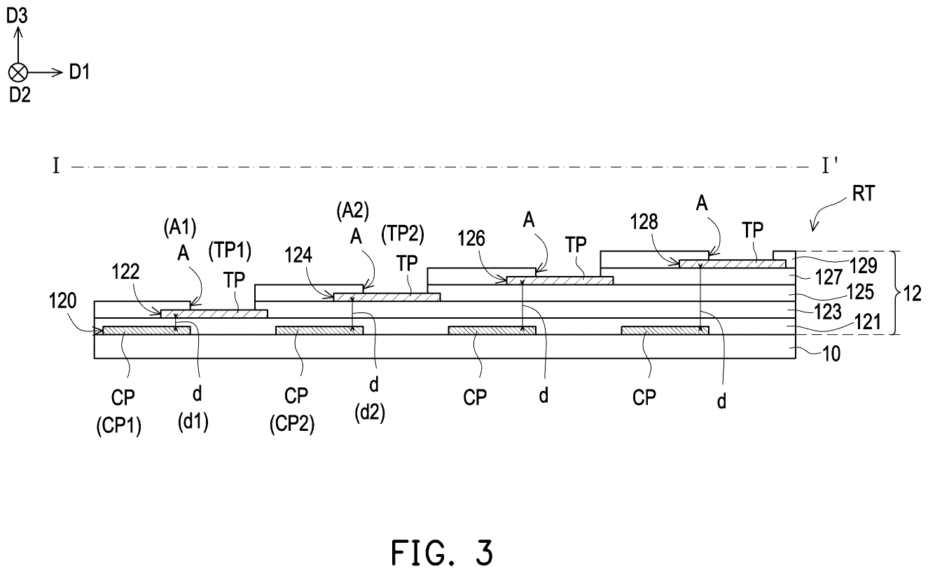

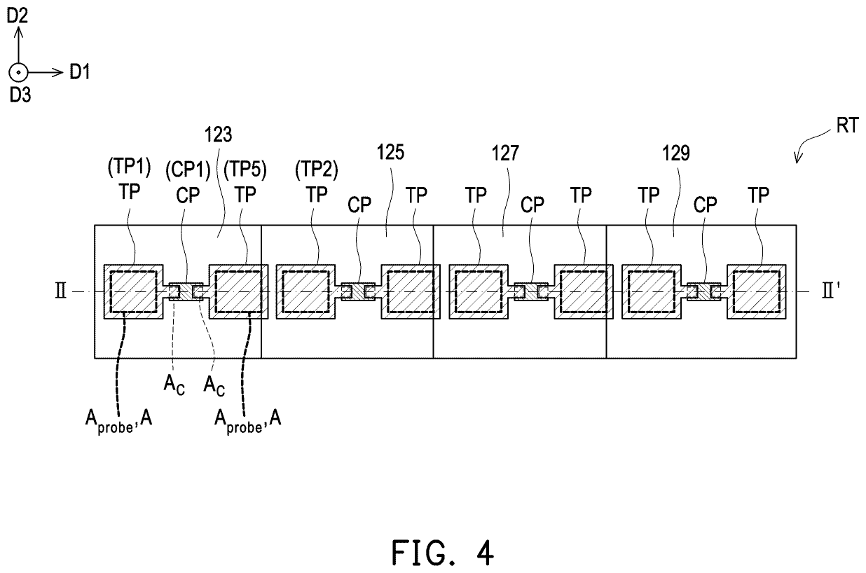

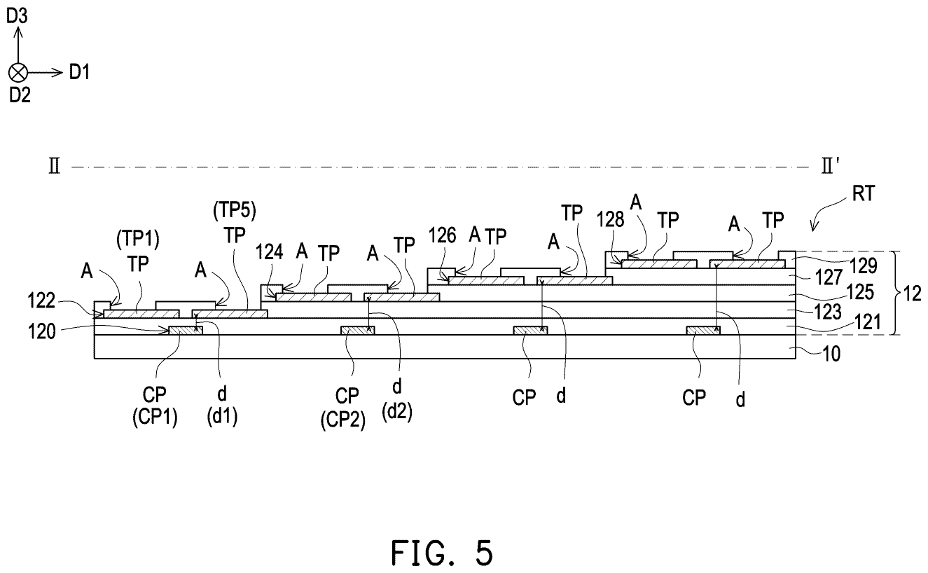

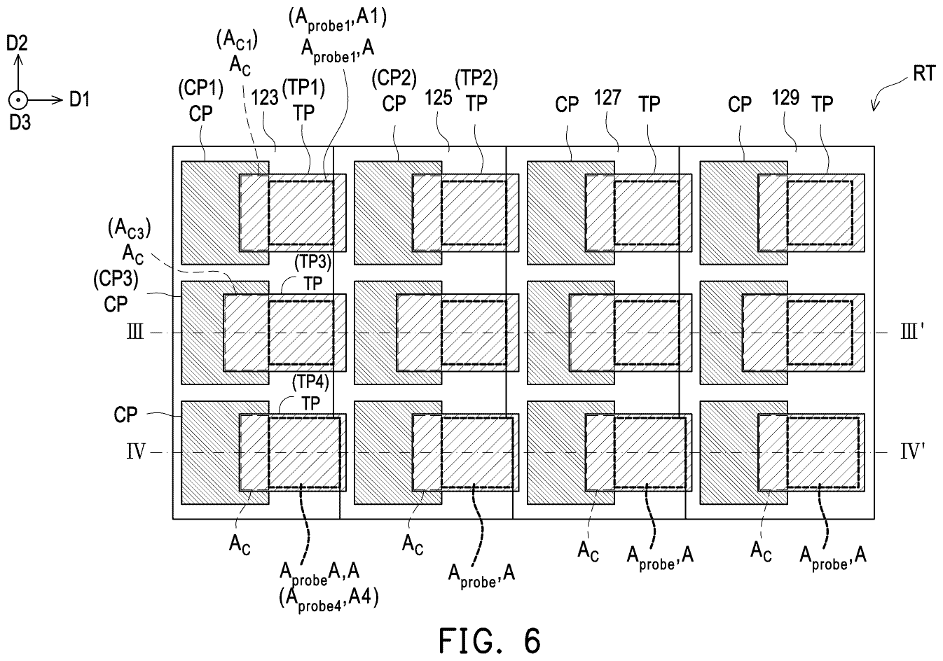

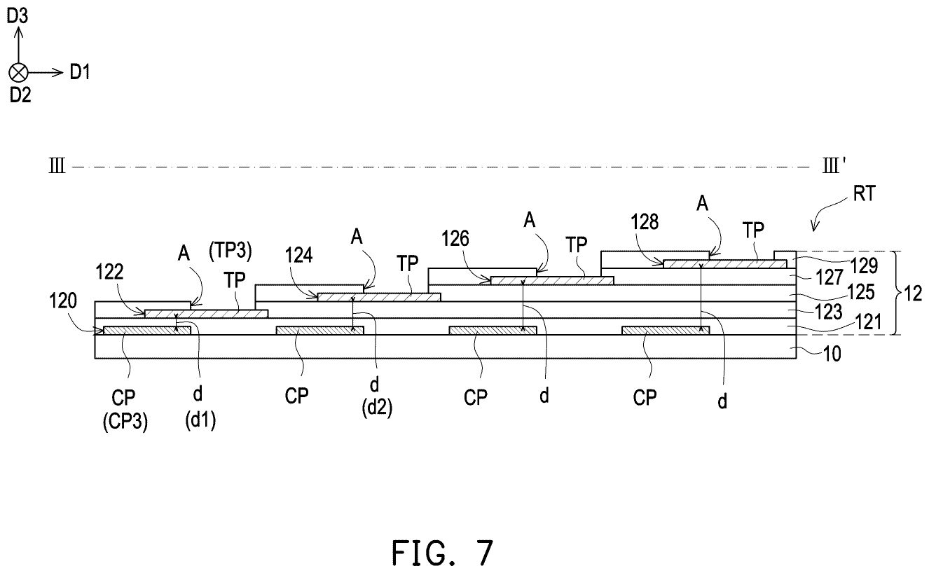

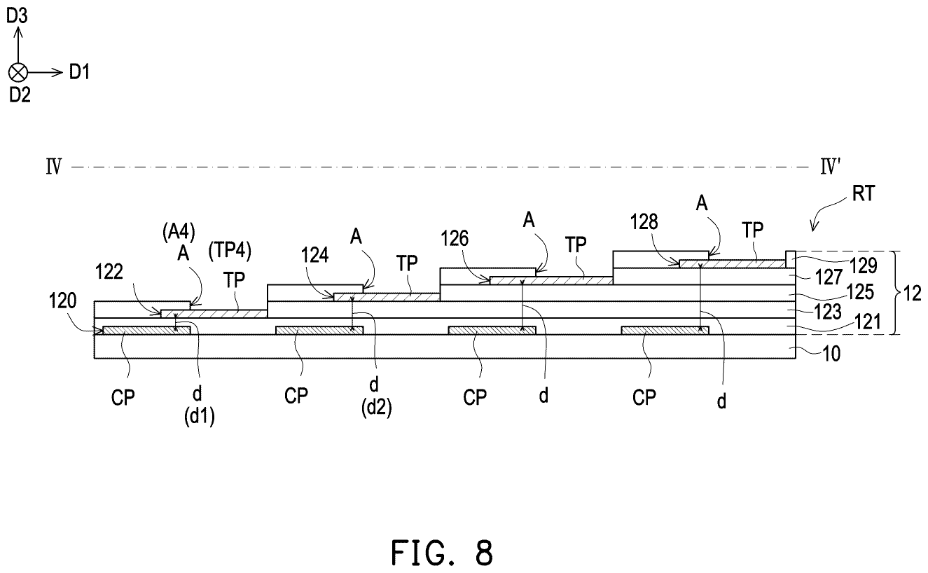

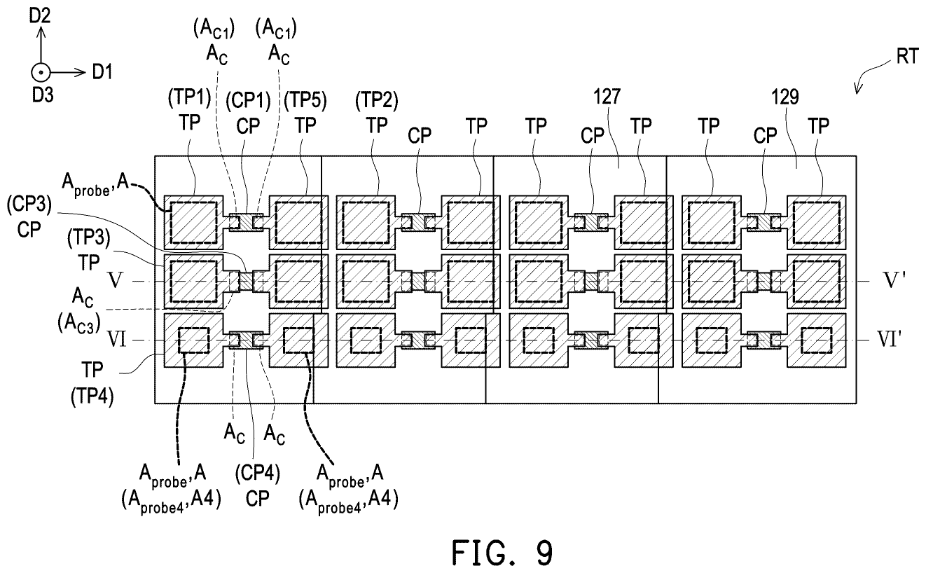

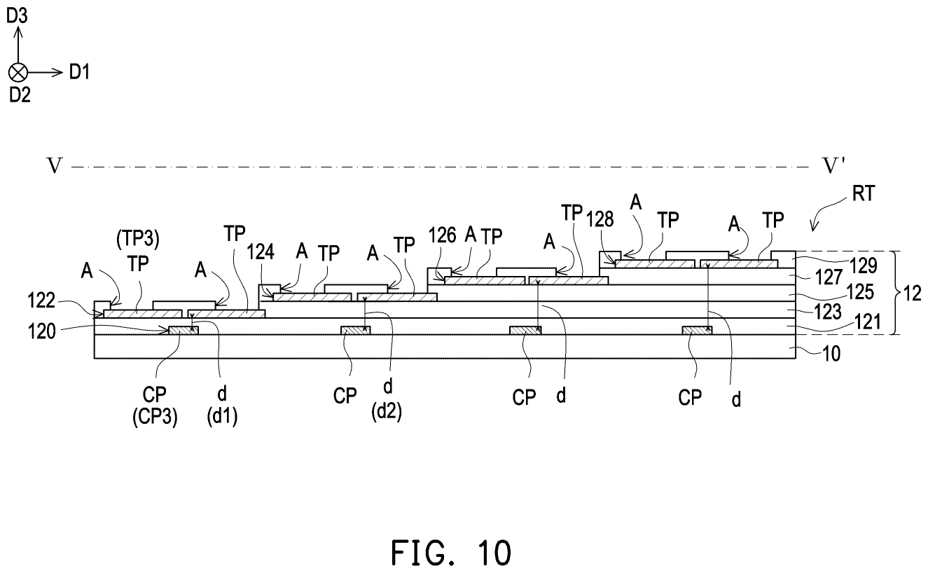

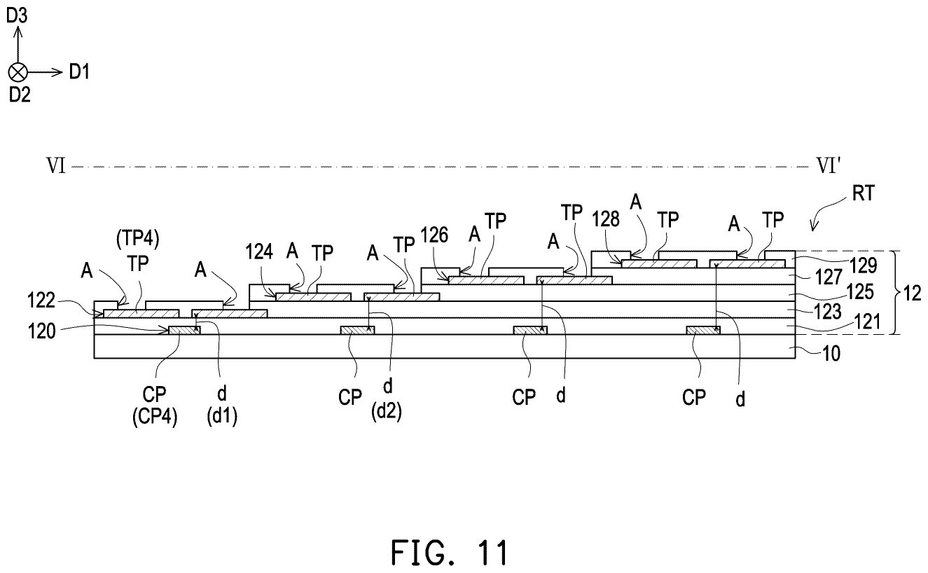

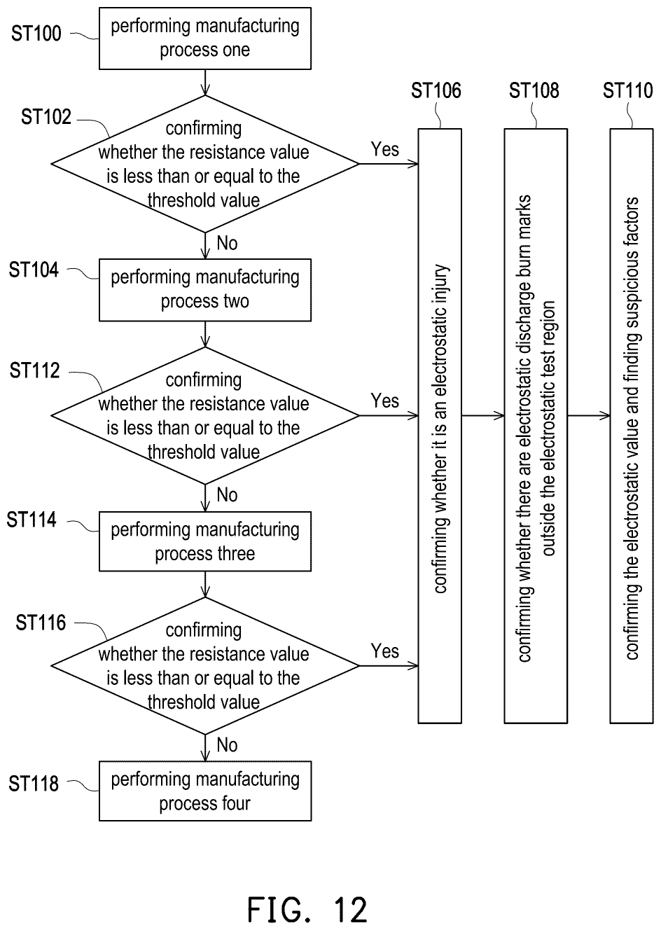

FIG. 1 is a schematic top view of a substrate circuit structure according to some embodiments of the disclosure. FIG. 2 is a first enlarged schematic diagram of an electrostatic test region in FIG. 1. FIG. 3 is a schematic cross-sectional view along a sectional line I-I′ in FIG. 2. FIG. 4 is a second enlarged schematic diagram of the electrostatic test region in FIG. 1. FIG. 5 is a schematic cross-sectional view along a sectional line II-II′ in FIG. 4. FIG. 6 is a third enlarged schematic diagram of the electrostatic test region in FIG. 1. FIG. 7 and FIG. 8 are schematic cross-sectional views taken along a sectional line III-III′ and a sectional line IV-IV′ in FIG. 6, respectively. FIG. 9 is a fourth enlarged schematic diagram of the electrostatic test region in FIG. 1. FIG. 10 and FIG. 11 are schematic cross-sectional views taken along a sectional line V-V′ and a sectional line VI-VI′ in FIG. 9, respectively. FIG. 12 is a schematic flowchart of an electrostatic discharge detection method according to some embodiments of the disclosure. It should be noted that the following embodiments can be replaced, reorganized, and mixed with features of several different embodiments without departing from the spirit of the disclosure to complete other embodiments. Features in various embodiments may be mixed and matched as long as they do not violate the spirit of the invention or conflict with each other.

Referring to FIG. 1 to FIG. 3, a substrate circuit structure 1 may include a substrate 10 and a circuit layer 12. The substrate 10 includes an active region R1 and a peripheral region R2 adjacent to the active region R1. The circuit layer 12 is disposed on the substrate 10 and includes an electrostatic test region RT disposed in at least one of the active region R1 and the peripheral region R2. The electrostatic test region RT includes a first test pad TP1 and a second test pad TP2. The first test pad TP1 corresponds to a first break down voltage. The second test pad TP2 is disposed adjacent to the first test pad TP1 and corresponds to a second break down voltage different from the first break down voltage.

In detail, the substrate 10 may be a rigid substrate or a flexible substrate. A material of the substrate SUB includes, for example, glass, quartz, ceramics, sapphire, or plastic, but not limited thereto. The plastic may include polycarbonate (PC), polyimide (PI), polypropylene (PP), polyethylene terephthalate (PET), and other suitable flexible materials or a combination of the aforementioned materials, but not limited thereto. In addition, the light transmittance of the substrate 10 is not limited, that is, the substrate 10 can be a light-transmitting substrate, a semi-light-transmitting substrate, or an opaque substrate.

According to different requirements, the substrate 10 can be divided into a variety of regions, such as the active region R1 and the peripheral region R2, but not limited thereto. The active region R1 may be disposed with active elements (e.g., switching elements such as transistors), passive elements (e.g., resistors, capacitors and/or inductors, etc.) or a combination of the above. Taking a display device as an example, the active region R1 can include a plurality of pixels to provide an image, and the peripheral region R2 can include peripheral circuits and/or driver chips, and the peripheral circuits can be used to electrically connect signal lines in the active region R1 to external circuits or the driver chips. In some embodiments, the peripheral region R2 may be located on one or more sides of the active region R1. In some embodiments, the peripheral region R2 may surround the active region R1, but not limited thereto.

In some embodiments, the substrate 10 may further include a redundant region R3 adjacent to the active region R1 and the peripheral region R2, and the circuit layer 12 may further include another electrostatic test region RT disposed in the redundant region R3. In some embodiments, as shown in FIG. 1, the substrate 10 may be a substrate that has not undergone a singulation process, and the substrate 10 may include a plurality of active regions R1, a plurality of peripheral regions R2 and the redundant region R3, wherein the plurality of active regions R1 are arranged in an array along a direction D1 and a direction D2. The direction D1 and the direction D2 intersect each other and are both perpendicular to a thickness direction (e.g., a direction D3) of the substrate 10. In some embodiments, the direction D1 and the direction D2 are perpendicular to each other, but not limited thereto. Each of the peripheral regions R2 is disposed on at least one side of a corresponding active region R1 and forms a singulation unit U with the corresponding active region R1. The redundant region R3 surrounds the plurality of singulation units U, for example. The redundant region R3 may include a plurality of scribe lines extending along the direction D1 or the direction D2. After the singulation process, the redundant region R3 is removed to form a plurality of singulation units U that are separated from each other. The substrate circuit structure 1 may include a substrate that has not undergone a singulation process (e.g., a substrate including the active regions R1, the peripheral regions R2, and the redundant region R3) or a substrate that has undergone a singulation process (e.g., a substrate including the active region R1 and the peripheral region R2 but excluding the redundant region R3).

The circuit layer 12 is disposed on the substrate 10. The location of the electrostatic test region RT of the circuit layer 12 is not limited. For example, the electrostatic test region RT can be disposed according to the product design, or the electrostatic test region RT can be disposed according to the high-risk region for electrostatic discharge. In some embodiments, the electrostatic test region RT can be disposed in the action region R1 to monitor the overall electrostatic status of the region that is more closely related to the actual product. In some embodiments, the electrostatic test region RT may be disposed in the peripheral region R2 to monitor high-risk region for electrostatic discharge. In some embodiments, the electrostatic test region RT can be disposed in the redundant region R3, so that the electrostatic test region RT has greater design flexibility and layout space. FIG. 1 schematically illustrates that each active region R1 is disposed with five electrostatic test regions RT, each peripheral region R2 is disposed with two electrostatic test regions RT, and the redundant region R3 is disposed with five electrostatic test regions RT. However, the number of electrostatic test regions RT in each region and their disposition positions can be changed according to actual needs and are not limited to those shown in FIG. 1.

The circuit layer 12 may include a plurality of conductive layers and a plurality of insulating layers. Taking FIG. 3 as an example, the circuit layer 12 may include a conductive layer 120, an insulating layer 121, a conductive layer 122, an insulating layer 123, a conductive layer 124, an insulating layer 125, a conductive layer 126, an insulating layer 127, a conductive layer 128 and an insulating layer 129 sequentially disposed on the substrate 10, but not limited thereto. According to different requirements, the circuit layer 12 may include more or less conductive layers and/or insulating layers. The materials of the conductive layer 120, the conductive layer 122, the conductive layer 124, the conductive layer 126 and the conductive layer 128 may include transparent conductive materials or opaque conductive materials. The transparent conductive materials may include metal oxides, graphene, other suitable transparent conductive materials, or a combination of the above. Metal oxides may include indium tin oxide, indium zinc oxide, aluminum tin oxide, aluminum zinc oxide, indium germanium zinc oxide, or other metal oxides. Opaque conductive materials may include metals, alloys, or a combination of the above. The materials of the insulating layer 121, the insulating layer 123, the insulating layer 125, the insulating layer 127 and the insulating layer 129 may include organic insulating materials, inorganic insulating materials or combinations thereof. Examples of organic insulating materials include polymethylmethacrylate (PMMA), epoxy, acrylic-based resin, silicone, polyimide polymer, or combinations of the above, but not limited thereto. Inorganic insulating materials include, for example, silicon oxide or silicon nitride, but are not limited thereto.

The electrostatic test region RT can adopt the stacked design of the circuit layer 12 itself and does not require additional manufacturing processes. Taking FIG. 2 and FIG. 3 as examples, the electrostatic test region RT may include a plurality of test pads TP, and the plurality of test pads TP may respectively belong to different conductive layers. For example, a first test pad TP1 and a second test pad TP2 in the plurality of test pads TP belong to the conductive layer 122 and the conductive layer 124, respectively.

According to the formula of a parallel plate capacitor, the electrostatic test region RT may also include a plurality of conductive patterns CP. For example, the electrostatic test region RT may also include a first conductive pattern CP1 at least partially overlapping the first test pad TP1 and a second conductive pattern CP2 at least partially overlapping the second test pad TP2, but not limited thereto. The plurality of conductive patterns CP belong to, for example, the same conductive layer, such as the conductive layer 120.

According to the formula of parallel plate capacitor, V_{bd}=E_{ds}*d′, wherein V_{bd} is the break down voltage, E_{ds} is the dielectric strength of the insulating layer material, and d′ is the thickness of the insulating layer. Under the same insulating layer material (i.e., the same E_{ds}), the break down voltage increases as the thickness of the insulating layer increases. That is to say, the break down voltage corresponding to the test pad TP can be adjusted by changing the distance (e.g., along the direction D3, the distance d between the lower surface of the test pad TP and the upper surface of the conductive pattern CP) between the test pad TP and the corresponding conductive pattern CP. In FIG. 3, a distance d1 between the first conductive pattern CP1 and the first test pad TP1 is different from a distance d2 between the second conductive pattern CP2 and the second test pad TP2, so that the first break down voltage corresponding to the first test pad TP1 is different from the second break down voltage corresponding to the second test pad TP2. In FIG. 3, the distance d between the test pad TP and the corresponding conductive pattern CP gradually increases from left to right, for example, so that the break down voltage corresponding to the four test pads TP gradually increases from left to right. For example, the break down voltages corresponding to the four test pads TP are 250 volts (V), 500 volts, 1000 volts and 2000 volts from left to right, but not limited thereto. In other embodiments, the electrostatic test region RT may include more test pads and/or more conductive patterns.

In addition to increasing the distance d between the test pad TP and the corresponding conductive pattern CP as mentioned above, the break down voltage corresponding to the test pad TP can also be adjusted by adjusting an overlapping area Ac between the conductive pattern CP and the corresponding test pad TP and/or adjusting an area A_{probe} of the test pad TP exposed by an aperture A of the insulating layer.

According to the formula of parallel plate capacitor, Eᵣₑₐₗ=Q_{probe}/(ε*A_{c}), wherein Eᵣₑₐₗ is the external electric field, Q_{probe} is the accumulated charge, ε is the dielectric coefficient of the insulating layer, and A_{c} is an overlapping area between the conductive pattern CP and the corresponding test pad TP. In the above formula, Q_{probe} is proportional to A_{probe}, wherein A_{probe} is the area of the test pad TP exposed by the aperture A of the insulating layer.

From the above description, it can be seen that under the same insulating layer material (i.e., the same ε), when A_{c} is the same, the larger the A_{probe}, the larger the Q_{probe} are, the larger the external electric field Eᵣₑₐₗ formed will be, so the easier it is for electrostatic injury to occur. In addition, under the same insulating layer material (i.e., the same ε), when the A_{probe} is the same, the Q_{probe} is also the same. The larger the A_{c}, the smaller the external electric field Eᵣₑₐₗ formed, so it is less likely to cause electrostatic injury. In some embodiments, the probability of ESD occurring in different test pad TPs can be further changed by changing at least one of A_{probe} and A_{c}, thereby observing the risk of ESD occurring at each manufacturing process site.

FIG. 2 and FIG. 3 illustrate an embodiment in which distances d between the test pads TP and the corresponding conductive patterns CP are different such that different test pads TP correspond to different break down voltages, wherein the overlapping area A_{c} of each conductive pattern CP and the corresponding test pad TP may be the same, and the area A_{probe} of each test pad TP exposed by the aperture A of the corresponding insulating layer may be the same. For example, the overlapping area A_{c1} between the first conductive pattern CP1 and the first test pad TP1 may be equal to the overlapping area A_{c2} between the second conductive pattern CP2 and the second test pad TP2. In addition, the electrostatic test region RT may include the insulating layer 123 and the insulating layer 125, wherein the insulating layer 123 includes a first aperture A1 that exposes the first test pad TP1, the insulating layer 125 includes a second aperture A2 that exposes the second test pad TP2, and the area A_{probe1} of the first test pad TP1 exposed by the first aperture A1 can be equal to the area A_{probe2} of the second test pad TP2 exposed by the second aperture A2. However, the disclosure is not limited to detecting different degrees of break down voltage values by changing the distance d between the test pad TP and the corresponding conductive pattern CP. In other embodiments, at least one of A_{probe} and A_{c} can be further changed to change the probability of ESD occurring in different test pad TPs.

In some embodiments, the plurality of conductive patterns CP may be electrically connected to a reference voltage, for example, the first conductive pattern CP1 and the second conductive pattern CP2 may be electrically connected to a reference voltage (e.g., V_{com}) in each manufacturing process. On the contrary, in order to detect the corresponding break down voltage value when electrostatic injury occurs, the plurality of test pads TP can be in a floating state without being electrically connected to other voltages. When the test pad(s) TP is/are damaged by electrostatic discharge, a short circuit will occur between the test pad TP and the corresponding conductive pattern CP. In some embodiments, a VOM meter (Volt-Ohm-Milli Am meter) can be used to measure the resistance between the test pad TP and the corresponding conductive pattern CP. If the resistance between the test pad TP and the corresponding conductive pattern CP is less than or equal to a threshold value (e.g., less than or equal to 1000 ohms), it means that the test pad TP and the corresponding conductive pattern CP are short-circuited, that is, the test pad TP may have suffered electrostatic injury; if the resistance value between the test pad TP and the corresponding conductive pattern CP is greater than the threshold value (e.g., greater than 1000 ohms), it means that the test pad TP and the corresponding conductive pattern CP are not short-circuited, that is, the test pad TP may not have suffered electrostatic injury. In addition, in the case where the test pad TP may have suffered electrostatic injury, further confirmation can be made through an optical microscope.

Referring to FIG. 4 and FIG. 5. In FIG. 2 and FIG. 3, the test pads TP and the conductive patterns CP have, for example, a one-to-one disposition relationship, while in FIG. 4 and FIG. 5, the test pads TP and the conductive patterns CP have, for example, a two-to-one disposition relationship. Specifically, two adjacent test pads TP correspond to the same break down voltage, and the two test pads TP at least partially overlap a conductive pattern CP, wherein each of the two test pads TP has the same overlapping area with the corresponding conductive pattern CP, and the area A_{probe} of each of the two test pads TP exposed by the aperture A of the corresponding insulating layer is the same. For example, as shown in FIG. 4 and FIG. 5, the electrostatic test region RT further includes a fifth test pad TP5 disposed adjacent to the first test pad TP1 and corresponding to the first break down voltage, wherein the fifth test pad TP5 at least partially overlaps the first conductive pattern CP1 and does not overlap the second conductive pattern CP2.

In some embodiments, the first test pad TP1 and the fifth test pad TP5 may be of equal potential. When the test pad TP suffers electrostatic injury, a short circuit will occur between the test pad TP and the corresponding conductive pattern CP. For example, the first test pad TP1 and the fifth test pad TP5 may be short-circuited due to electrostatic injury. In some embodiments, a VOM meter can be used to measure the resistance between two test pads TP overlapping the same conductive pattern CP. If the resistance between the two test pads TP is less than or equal to the threshold value (e.g., less than or equal to 1000 ohms), it means that a short circuit may be formed between any of the two test pads TP and the conductive pattern CP, or between the two test pads TP such that the resistance value is reduced, that is, the test pads TP may have suffered electrostatic injury; if the resistance between the two test pads TP is greater than the threshold value (e.g., greater than 1000 ohms), it means that there is no short circuit between any of the two test pads TP and the conductive pattern CP, and there is no short circuit between the two test pads TP, that is, the test pads TP may not have suffered electrostatic injury. In the case where the test pads TP may have suffered electrostatic injury, further confirmation can be made through an automatic optical inspection system.

Referring to FIG. 6 to FIG. 8. The cross-sectional views of the first to third horizontal rows from top to bottom in FIG. 6 can be referred to FIG. 3, FIG. 7 and FIG. 8, respectively. In FIG. 6, the distances d between multiple test pads TP in the same straight row and the corresponding multiple conductive patterns CP are all the same, and the distances d between multiple test pads TP in different straight rows and the corresponding multiple conductive patterns CP are all different, so that multiple test pads TP in the same straight row correspond to a similar break down voltage, and multiple test pads TP in different straight rows correspond to different break down voltages.

The difference between the second horizontal row and the first horizontal row counting from top to bottom in FIG. 6 mainly lies in the difference in overlapping area A_{c}. For example, electrostatic test region RT further includes a third test pad TP3 disposed adjacent to the first test pad TP1 and a third conductive pattern CP3 at least partially overlapping the third test pad TP3, wherein the distance d (e.g., the distance d1) between the first conductive pattern CP1 and the first test pad TP1 is equal to the distance d between the third conductive pattern CP3 and the third test pad TP3, and the overlapping area A_{c3} between the third conductive pattern CP3 and the third test pad TP3 is different from the overlapping area A_{c1} between the first conductive pattern CP1 and the first test pad TP1. Taking FIG. 6 as an example, the overlapping area A_{c} of the second horizontal row can be larger than the overlapping area A_{c} of the first horizontal row, making the second horizontal row less prone to electrostatic injury than the first horizontal row, but not limited thereto. In other embodiments, although not shown, the overlapping area A_{c} of the second horizontal row may be smaller than the overlapping area Ac of the first horizontal row, so that the second horizontal row is more susceptible to electrostatic injury than the first horizontal row.

The difference between the third horizontal row and the first horizontal row from top to bottom in FIG. 6 mainly lies in the difference in the area A_{probe} of the test pad TP exposed by the aperture A of the corresponding insulating layer. For example, the electrostatic test region RT further includes a fourth test pad TP4 disposed adjacent to the first test pad TP1 and a conductive pattern CP disposed adjacent to the first conductive pattern CP1 and at least partially overlapping the fourth test pad TP4, wherein the distance d (e.g., the distance d1) between the first conductive pattern CP1 and the first test pad TP1 is equal to the distance d between the conductive pattern CP and the fourth test pad TP4, the insulating layer 123 further includes an aperture A4 exposing the fourth test pad TP4, and the area A_{probe1} of the first test pad TP1 exposed by the first aperture A1 is different from the area A_{probe4} of the fourth test pad TP4 exposed by the fourth aperture A4. Taking FIG. 6 as an example, the A_{probe} of the third horizontal row can be larger than the A_{probe} of the first horizontal row, making the third horizontal row more susceptible to electrostatic injury than the first horizontal row, but not limited thereto. In other embodiments, although not shown, the A_{probe} of the third row may be smaller than the A_{probe} of the first row, so that the third row is less susceptible to electrostatic injury than the first row.

As mentioned earlier, in addition to increasing the distance d between the test pad TP and the corresponding conductive pattern CP, the break down voltage corresponding to the test pad TP may also be adjusted by adjusting the overlapping area A_{c} between the conductive pattern CP and the corresponding test pad TP and/or adjusting the area A_{probe} of the test pad TP exposed by the aperture A of the insulating layer.

Therefore, in the embodiments of FIG. 6 to FIG. 8, the overlapping area A_{c} between the

conductive pattern CP and the corresponding test pad TP is adjusted, and the area A_{probe} of the test pad TP exposed by the aperture A of the insulating layer is adjusted to fine-tune the break down voltage of the corresponding test pad TP so as to detect more precise break down voltage values. For example, the leftmost test pad TP in the first horizontal row can correspond to a break down voltage of 250 volts, the leftmost test pad TP in the second horizontal row can correspond to a break down voltage of 300 volts, and the leftmost test pad in the third horizontal row can correspond to a break down voltage of 200 volts, and so on for other test pads TP.

Referring to FIG. 9 to FIG. 11. The cross-sectional views of the first to third rows from top to bottom in FIG. 9 can be referred to FIG. 5, FIG. 10 and FIG. 11, respectively. In FIG. 9, the distances d between multiple test pads TP in the same straight row and the corresponding multiple conductive patterns CP are all the same, and the distances d between multiple test pads TP in different straight rows and the corresponding multiple conductive patterns CP are all different, so that multiple test pads TP in the same straight row corresponds to the same break down voltage, and multiple test pads TP in different straight rows corresponds to different break down voltages.

Similar to FIG. 6, the difference between the second horizontal row and the first horizontal row from top to bottom in FIG. 9 mainly lies in the difference in overlapping area A_{c}. For example, the overlapping area A_{c} of the second horizontal row can be larger than the overlapping area A_{c} of the first horizontal row, making the second horizontal row less prone to electrostatic injury (corresponding to a higher break down voltage) than the first horizontal row, but not limited thereto. In other embodiments, although not shown, the overlapping area A_{c} of the second horizontal row may be smaller than the overlapping area A_{c} of the first horizontal row, so that the second horizontal row is more susceptible to electrostatic injury (corresponding to a lower break down voltage) than the first horizontal row.

The difference between the third horizontal row and the first horizontal row from top to bottom in FIG. 9 is mainly lies in the area A_{probe} of the test pad TP exposed by the aperture A of the corresponding insulating layer. For example, the A_{probe} of the third horizontal row can be smaller than the A_{probe} of the first horizontal row, so that the third horizontal row is less prone to electrostatic injury (corresponding to a higher break down voltage) than the first horizontal row, but not limited thereto. In other embodiments, although not shown, the A_{probe} of the third row may be larger than the A_{probe} of the first row, so that the third row is more susceptible to electrostatic injury (corresponding to a lower break down voltage) than the first horizontal row.

The electrostatic discharge detection method may include measuring the resistance of the test pads before performing the next manufacturing process. If the measured resistance value is greater than the threshold value, the next process is performed. If the measured resistance value is less than or equal to the threshold value, further confirm may be made to determine whether it is an electrostatic injury.

Taking FIG. 12 as an example, the electrostatic discharge detection method may include performing manufacturing process one (step ST100). For example, the manufacturing process one can be one of the manufacturing processes for manufacturing a panel or a semiconductor element, such as a photoresist coating process, but not limited thereto.

After completing the manufacturing process one and before performing the next manufacturing process (such as a manufacturing process two), whether the resistance value is less than or equal to the threshold value may be confirmed first (step ST102). For example, two pointers of the VOM meter can be respectively contacted with a test pad TP in FIG. 2 or FIG. 6 and a detection pad (not shown) electrically connected to the plurality of conductive patterns CP to confirm whether the resistance value between the test pad and the detection pad is less than or equal to the threshold value; alternatively, the two pointers of the VOM meter can be respectively contacted with two adjacent test pads TP that overlap the same conductive pattern CP in FIG. 3 or FIG. 9 to confirm whether the resistance value between the two adjacent test pads TP is less than or equal to the threshold value.

If the resistance value exceeds the threshold value, the manufacturing process two is performed (step ST104). The manufacturing process two may also be one of the processes for manufacturing a panel or a semiconductor element, such as an exposure process, but not limited thereto. If the resistance value is less than or equal to the threshold value, whether it is an electrostatic injury is confirmed (step ST106). For example, an optical microscope can be used to confirm the type of defect of the detection pad. Next, an automated optical inspection (AOI) system can be used to confirm whether there are electrostatic discharge burn marks outside the electrostatic test region (step ST108). Then, the electrostatic value (e.g., the electrostatic value of the undergone manufacturing process, machine and/or environment) is confirmed to find suspicious factors (step ST110). This can be used to determine how to improve the manufacturing process, machine, and/or environment to reduce electrostatic discharge phenomena, or to determine how to improve the electrostatic protection capability of the electrostatic discharge region during product design.

After completing the manufacturing process two and before performing the next manufacturing process (such as a manufacturing process three), whether the resistance value is less than or equal to the threshold value may be confirmed first (step ST112). The method of confirming the resistance value can be referred to the above and will not be repeated here.

If the resistance value exceeds the threshold value, the manufacturing process three is performed (step ST114). The manufacturing process three may also be one of the processes for manufacturing a panel or a semiconductor element, such as a developing process, but not limited thereto. If the resistance value is less than or equal to the threshold value, step ST106, step ST108 and step ST110 can be continued.

After completing the manufacturing process three and before performing the next process (such as a manufacturing process four), whether the resistance value is less than or equal to the threshold value may be confirmed first (step ST116). The method of confirming the resistance value can be referred to the above and will not be repeated here.

If the resistance value exceeds the threshold value, the manufacturing process four is performed (step ST118). The manufacturing process four may also be one of the processes for manufacturing a panel or a semiconductor element, such as an etching process, but not limited thereto. If the resistance value is less than or equal to the threshold value, step ST106, step ST108 and step ST110 can be continued.

It should be understood that FIG. 12 is only an example. In other embodiments, more manufacturing processes and more resistance value confirmation steps may be included, and the number of manufacturing processes and/or resistance value confirmation steps may not be limited.

In summary, in embodiments of the disclosure, an electrostatic test region can be disposed in at least one of the active region and the peripheral region of the substrate to monitor the electrostatic discharge phenomenon during the manufacturing process. In this way, corresponding corrections or designs can be made based on the monitoring results, thereby improving product yield or reliability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

Although the embodiments and the advantages thereof have been disclosed as above, it should be understood that, a person skilled in the art may make variations, replacements, and modifications, and features among the embodiments may be arbitrarily mixed and replaced with each other into other newly formed embodiments without departing from the spirit and scope of the disclosure. In addition, the protection scope of the disclosure is not limited to the process, machine, manufacture, composition of matters, device, method, or step in the specifically described embodiments in the description. A person skilled in the art can understand from the content of the disclosure that the existing or to-be-developed process, machine, manufacture, composition of matters, device, method, or step may be used according to the disclosure as long as the substantially same function can be implemented or the substantially same result can be obtained in the embodiments described herein. Therefore, the protection scope of the disclosure includes the above-mentioned process, machine, manufacture, composition of matters, device, method, or step. Moreover, each claim forms an individual embodiment, and the protection scope of the disclosure also includes a combination of each of the claims and embodiments. The protection scope of the disclosure should be subject to the appended claims.

What is claimed is:

1. A substrate circuit structure, comprising:
a substrate comprising an active region and a peripheral region adjacent to the active region; and
a circuit layer disposed on the substrate and comprising an electrostatic test region disposed in at least one of the active region and the peripheral region, wherein the electrostatic test region comprises:
a first test pad corresponding to a first break down voltage; and
a second test pad disposed adjacent to the first test pad and corresponding to a second break down voltage different from the first break down voltage.

2. The substrate circuit structure according to claim 1, wherein the electrostatic test region further comprises:
a first conductive pattern at least partially overlapping the first test pad; and
a second conductive pattern at least partially overlapping the second test pad.

3. The substrate circuit structure according to claim 2, wherein the first conductive pattern and the second conductive pattern belong to a same conductive layer.

4. The substrate circuit structure according to claim 2, wherein the first conductive pattern and the second test pad do not overlap each other, and the second conductive pattern and the first test pad do not overlap each other.

5. The substrate circuit structure according to claim 2, wherein a distance between the first conductive pattern and the first test pad is different from a distance between the second conductive pattern and the second test pad.

6. The substrate circuit structure according to claim 2, wherein an overlapping area between the first conductive pattern and the first test pad is equal to an overlapping area between the second conductive pattern and the second test pad.

7. The substrate circuit structure according to claim 2, wherein the first conductive pattern, the second conductive pattern, the first test pad and the second test pad are separated from each other.

8. The substrate circuit structure according to claim 2, wherein the electrostatic test region further comprises:
an insulating layer comprising a first aperture exposing the first test pad; and
another insulating layer comprising a second aperture exposing the second test pad, wherein an area of the first test pad exposed by the first aperture is equal to an area of the second test pad exposed by the second aperture.

9. The substrate circuit structure according to claim 8, wherein a portion of the insulating layer is disposed between the substrate and the another insulating layer.

10. The substrate circuit structure according to claim 8, wherein the first aperture and the first conductive pattern do not overlap with each other, and the second aperture and the second conductive pattern do not overlap with each other.

11. The substrate circuit structure according to claim 8, wherein the electrostatic test region further comprises:
a third test pad disposed adjacent to the first test pad; and
a third conductive pattern disposed adjacent to the first conductive pattern and at least partially overlapping the third test pad;
wherein a distance between the first conductive pattern and the first test pad is equal to a distance between the third conductive pattern and the third test pad, and the insulating layer further comprises a third aperture exposing the third test pad, and the area of the first test pad exposed by the first aperture is different from an area of the third test pad exposed by the third aperture.

12. The substrate circuit structure according to claim 11, wherein an overlapping area between the first conductive pattern and the first test pad is equal to an overlapping area between the third conductive pattern and the third test pad.

13. The substrate circuit structure according to claim 2, wherein the electrostatic test region further comprises:
a fourth test pad disposed adjacent to the first test pad; and
a fourth conductive pattern at least partially overlapping the fourth test pad, wherein a distance between the first conductive pattern and the first test pad is equal to a distance between the fourth conductive pattern and the fourth test pad, and an overlapping area between the fourth conductive pattern and the fourth test pad is different from an overlapping area between the first conductive pattern and the first test pad.

14. The substrate circuit structure according to claim 13, the insulating layer further comprises a fourth aperture exposing the fourth test pad, and an area of the first test pad exposed by the first aperture is equal to an area of the fourth test pad exposed by the fourth aperture.

15. The substrate circuit structure according to claim 2, wherein the electrostatic test region further comprises:
a fifth test pad disposed adjacent to the first test pad and corresponding to the first break down voltage, wherein the fifth test pad at least partially overlaps the first conductive pattern and does not overlap the second conductive pattern.

16. The substrate circuit structure according to claim 15, wherein a distance between the first conductive pattern and the first test pad is equal to a distance between the first conductive pattern and the fifth test pad.

17. The substrate circuit structure according to claim 15, wherein an overlapping area between the first conductive pattern and the first test pad is equal to an overlapping area between the first conductive pattern and the fifth test pad.

18. The substrate circuit structure according to claim 15, wherein the electrostatic test region further comprises:
an insulating layer comprising a first aperture exposing the first test pad and a fifth aperture exposing the fifth test pad, wherein an area of the first test pad exposed by the first aperture is equal to an area of the fifth test pad exposed by the fifth aperture.

19. The substrate circuit structure according to claim 2, wherein the first conductive pattern and the second conductive pattern are electrically connected to a reference voltage.

20. The substrate circuit structure according to claim 1, wherein the substrate further includes a redundant region adjacent to the active region and the peripheral region, and the circuit layer further comprises another electrostatic test region disposed in the redundant region.
